(19) United States
(12) Patent Application Publication
(10) Pub. No.: US 2008/0150159 A1
(43) Pub. Date: Jun. 26, 2008

(54) Semiconductor Package with Perforated Substrate

(76) Inventors: Irwin Aberin, Singapore (SG); Gerald Ofner, Singapore (SG); Alfred Swain Hong Yeo, Singapore (SG); Wen Hui Zhu, Singapore (SG)

Correspondence Address: DICKE, BILLIG & CZAJA, FIFTH STREET TOWERS, 100 SOUTH FIFTH STREET, SUITE 2250, MINNEAPOLIS, MN, 55402, US

(21) Appl. No.: 10/588,927

(22) PCT Filed: Feb. 11, 2004
(86) PCT No.: PCT/IB2004/000341

§ 371 Date: Aug. 3, 2007

(51) Int. Cl. H01L 23/48; H05K 3/42; H01L 21/56; H05K 1/00

(52) U.S. Cl. 257/778; 29/852; 174/263; 438/127; 257/E23.01; 257/E21.502

(57) ABSTRACT

A semiconductor package includes a substrate and a semiconductor chip which includes an active surface with a plurality of chip contact areas. The chip is electrically connected to the substrate. The substrate includes a sheet of core material, a plurality of upper conducting traces and upper contact pads on its upper surface, a second plurality of lower conductive traces and external contact areas on its bottom surface. A plurality of conducting vias connect the conducting traces and lower conducting traces. The substrate also includes a plurality of vent holes and a layer of solder resist covering the upper and lower surfaces of the substrate leaving the contact areas free from solder resist.

The invention relates to a semiconductor package and to a substrate for a semiconductor package, and to methods for assembling the substrate and semiconductor package.

The performance and reliability of semiconductor packages is limited by stresses within the package which occur during the manufacturing process.

JP 3283453 discloses a semiconductor package which includes a moisture absorbing material bonded to the rear of the die pad. KR 2002064592-A discloses a semiconductor package which includes a vent hole. These packages are not very reliable and many packages are discarded after manufacturing.

It is one object of the invention to provide a more reliable semiconductor package and a simple, cost-effective method for assembling such a package.

This object of the invention is solved by the subject matter of the independent claims. Further improvements arise from the subject matter of the dependent claims.

A semiconductor package according to the invention comprises a substrate and a semiconductor chip which includes an active surface with a plurality of chip contact areas. The chip contact areas are electrically connected to the upper contact areas of the substrate. The substrate comprises, for example, a redistribution board.

The substrate for a semiconductor package according to the invention includes a perforated sheet of core material. The core material comprises an electrically insulating or dielectric material such as a plastic or a ceramic or a BT substrate.

The substrate also includes a plurality of upper conducting traces and upper contact pads or areas on its upper surface and a second plurality of lower conductive traces and external contact areas on its bottom surface. A plurality of conducting vias which are positioned essentially vertically through the thickness of the substrate and electrically connect the upper conducting traces and lower conducting traces of the substrate. A plurality of vent holes or non-plated through holes is provided. A layer of solder resist covers the upper and lower surfaces of the substrate leaving the contact areas free from solder resist.

The non-plated through holes or vent holes are positioned essentially vertically in the substrate and penetrate the upper and lower surfaces of the substrate forming open-ended through holes. The vent holes have a diameter of preferably approximately 1 μm to approximately 5 mm or more preferably approximately 10 μm to approximately 0.5 mm or even more preferably approximately 100 μm.

The diameters of the through holes have the advantage that the non-plated through holes are positioned laterally between the conducting traces and contact areas on the upper and lower surface of the substrate. The conducting paths are, therefore, not disrupted by the position of the vent holes. Advantageously, the vent holes are included in a standard substrate which already includes conducting traces and contacts areas in a desired arrangement or design.

Analysis by the inventors has shown that the invention reduces stresses inside the package during the manufacturing process, particularly during the solder reflow process, leading to an improved reliability of the packages. This is the case even when there is moisture inside semiconductor packages.

The non-plated through holes included in the substrate of the invention have the advantage that moisture escapes from the core material of the substrate through the side walls of the non-plated through holes as the side walls of the vent holes include no metal or electrically conducting coating or layer.

The metal electro-plated coating on the inner walls of the conducting vias is impermeable to moisture. The metal coating of the conducting vias therefore prevents moisture from escaping from the core material through the centre of the via. The inclusion of the non-plated through holes in the substrate of the invention is, therefore, extremely advantageous as moisture escapes from the package in a three-dimensional way.

The substrate according to the invention is advantageously used in a semiconductor package, such as a laminate package which includes a substrate, for example, flip-chip or ball grid array packages. Preferably, the chip is mounted to the substrate by the flip chip technique. Microscopic solder balls connect the chip contact areas to the upper contact areas of the substrate. Preferably the area between the active surface of the chip and the upper surface of the substrate is underfilled by epoxy resin or underfill material. This has the advantage that the delicate electrical connections formed by the microscopic solder balls are protected.

In an alternative embodiment, the chip is encapsulated by mold material. This has the advantage of protecting the outer surface of the chip and upper surface of the package.

The plurality of vent holes are advantageously laterally located towards the centre of the substrate. This advantageously enables moisture in the core material at the centre of the substrate to escape through the vent holes. As the vent holes are positioned in the substrate under the chip and underfill material, the vent holes act as a channel for moisture relief from the underfill material and chip and from the interfaces between the chip, underfill material and substrate. The vent holes provide an efficient moisture relief path, reducing stress at the interfaces and package reliability is improved.

Alternatively, the plurality of vent holes are laterally located towards the centre and towards the outer edges of the substrate. This arrangement of the vent holes is particularly advantageous if the chip is overmolded or encapsulated by, for example, mold material or plastic as moisture escapes from the mold material through the vent holes as well as from the outer surfaces. The escape of moisture from the package is therefore enhanced.

In one embodiment of the invention the non-plated through holes or vent holes include solder resist. Alternatively, the vent holes are filled by solder resist. This has the advantage that moisture more easily escapes from the package as solder resist is extremely permeable to moisture.

In an embodiment of the invention the vent holes are closed at one end by a layer of solder resist on the upper surface of the substrate. This has the advantage that the solder resist layer is more easily applied to the substrate.

The arrangements of the solder resist have the advantage that underfill material or mold material does not enter the vent holes. As mold material is not permeable to moisture, this has the advantage that the vent holes are not filled or partially filled by moisture blocking material and moisture can more easily escape from the package through the vent holes.

A method to assemble a substrate for a semiconductor package comprises the following steps. Firstly a substrate is provided. The substrate comprises a sheet of core material, a plurality of upper contact traces and upper contact pads on its upper surface, a second plurality of lower conducting traces and external contact areas on its bottom surface and conducting vias connecting the upper conducting traces and lower conducting traces. A plurality of vent holes is then formed in the substrate.

The upper and lower surfaces of the substrate are covered by a layer of solder resist leaving the upper and lower contact areas free from solder resist.

Alternatively, the vent holes are formed in the core material before a plurality of upper contact traces and upper contact pads on its upper surface, a second plurality of lower conducting traces and external contact areas on its bottom surface and conducting vias are deposited.

Preferably, the vent holes are formed by drilling.

A method to assemble a semiconductor package comprises the following steps. A semiconductor chip comprising an active surface including a plurality of chip contact areas and a substrate as described above is provided.

The chip is mounted on the upper surface of a substrate according to the invention by microscopic solder balls between the chip contacts and upper contact areas. A solder reflow is performed. The area between the chip and the upper surface of the substrate is underfilled with epoxy resin and external contacts such as solder balls are attached to the external contact areas of the substrate.

In an embodiment the upper surface of the chip and substrate are covered with mold material to encapsulate the chip.

It is an object of the invention to improve the performance and reliability of semiconductor or IC packages. The non-plated through holes or vent holes provided in the substrate provide paths or channels for the free and easy emission of moisture from the package. This is particularly advantageous during the solder reflow process when the package is heated.

The size and distribution of the non-plated through holes within the substrate are chosen so that the channels and surfaces formed by the holes provide an efficient moisture relief from the package in a three-dimensional way.

Semiconductor packages containing the perorated substrate according to the invention do not suffer high vapour pressure and high moisture content in the interface between the semiconductor chip or die and the die attach or underfill material, the interface between the die attach or underfill material and the substrate, the interface between the mold material or molding compound or plastic housing and the substrate and more advantageously within the substrate. Hygroscopic stresses are reduced by use of the substrate according to the invention and the reliability of the packages is improved. Stresses within and warping of packages which include a perforated substrate according to the invention are reduced and the performance and reliability improved.

An embodiment of the invention will now be described by way of example with reference to the drawings.

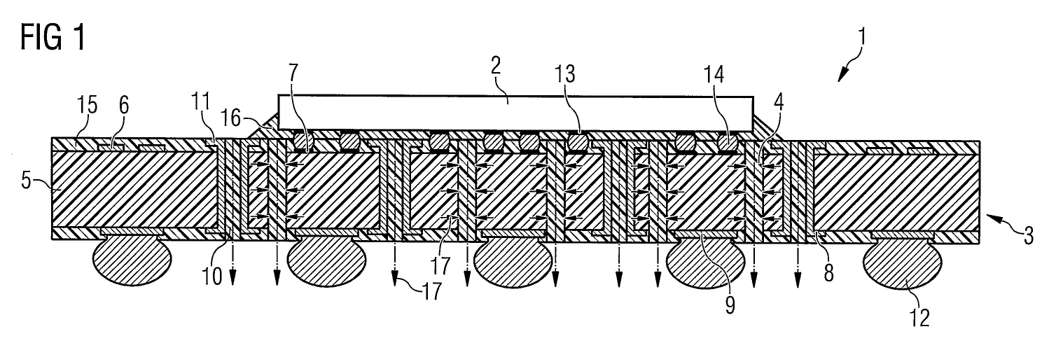

FIG. 1 shows a flip-chip semiconductor package including an exposed semiconductor chip,

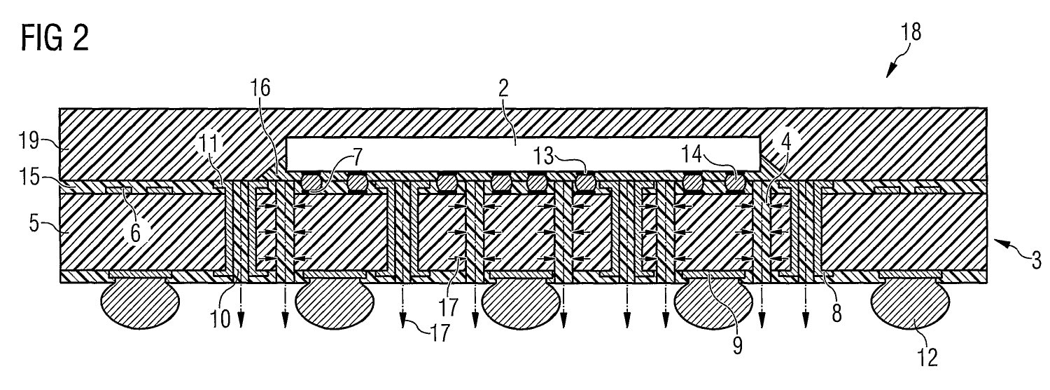

FIG. 2 shows a cross-sectional view of a flip-chip semiconductor package including an overmolded semiconductor chip,

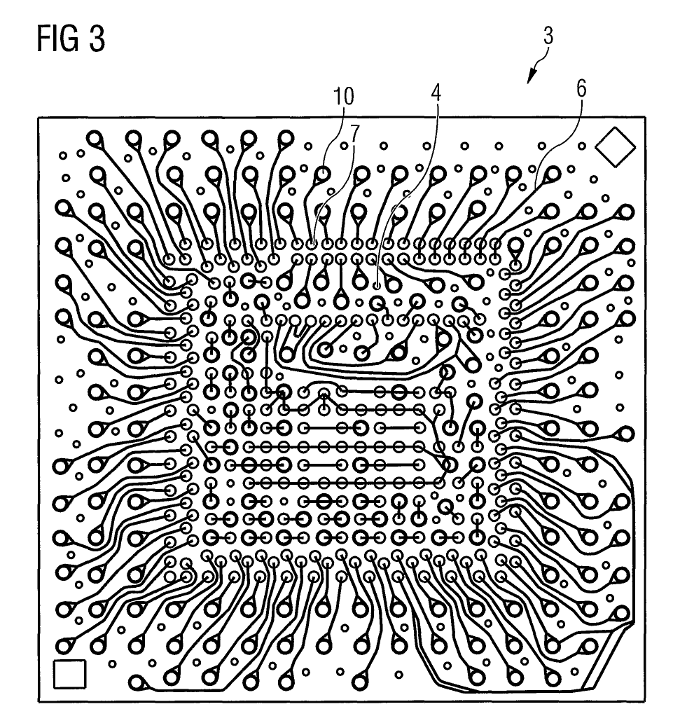

FIG. 3 shows a top view of the upper surface of the substrate of the semiconductor package of FIG. 1 or FIG. 2, and

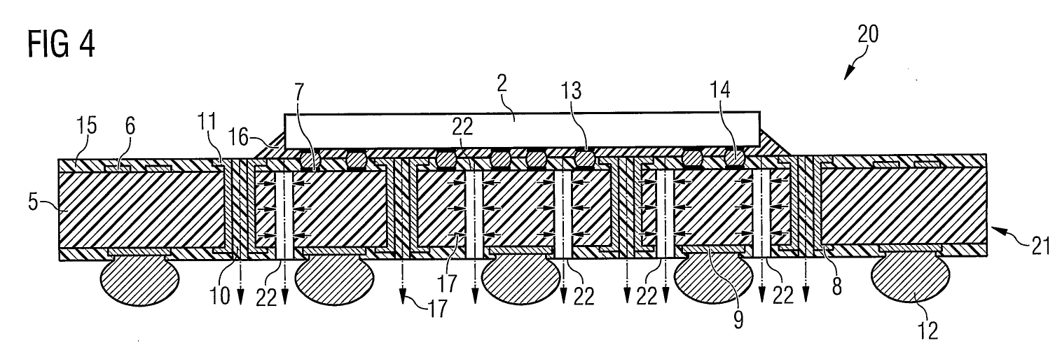

FIG. 4 shows a cross-sectional view of an alternative embodiment of a flip-chip package.

FIG. 1 shows a cross-sectional view of a semiconductor package 1 which includes an exposed semiconductor chip 2 mounted by the flip-chip technique to a redistribution board 3.

The redistribution board 3 comprises a sheet of core material 5 and includes a plurality of upper conducting traces 6 and upper contact pads 7 on its upper surface and a second plurality of lower conductive traces 8 and external contact areas 9 on its bottom surface.

The redistribution board 3 also includes a plurality of essentially vertical plated via holes or conducting vias 10 which penetrate the redistribution board from the upper to lower surface. The inner surfaces of the plated via holes 10 are covered by an electrically conducting coating 11 deposited by an electro-plating technique. The upper contact pads 7 on the upper surface of the redistribution board 3 are electrically connected with an external contact area 9 on the bottom surface of the redistribution board 3 by a continuous conducting path formed by upper conductive traces 6, the conducting coating 11 of via holes 10 and the second lower conductive traces 8. A complete conducting path is not seen for every upper contact pad 7 or external contact area 9 in the cross-section of FIG. 1 due to the lateral positioning of the upper contact pads 7, external contact areas 9 and conductive traces 6 and 8. The lateral positioning of the upper conducting traces 6 and upper contact pads 7 can be more clearly seen in the top view of FIG. 3 which is described later.

The redistribution board 3 also includes a plurality of non-plated through holes or vent holes 4 which are positioned essentially vertically and penetrate the redistribution board from the upper to the lower surface. The inner surface of the non-plated through holes 4 does not include a metal coating. The non-plated through holes 4 are laterally positioned in the redistribution board 3 in areas which do not include conductive traces or contact areas on either the upper or lower surface. The non-plated through holes 4 and plated via holes 10 are located laterally throughout the redistribution board 3; Some are positioned in the redistribution board 3 towards the lateral centre so that they are under the chip 2 and others are positioned towards the outer edges of the redistribution board 3 so that they are laterally adjacent to the chip 2.

Solder balls 12 are attached to the external contact areas 9 to provide the electrical connection from the package 1 to an external circuit board (which is not shown in the Figure).

The semiconductor chip 2 comprises an active surface including a plurality of chip contact areas 13 and a passive surface. The chip 2 is electrically connected to the redistribution board 3 by microscopic solder balls 14 between the chip contact areas 13 and the upper contact pads 7 on the upper surface of the redistribution board 3.

The upper and lower surfaces of the redistribution board are coated with a layer of solder resist 15. The volume of the plated via holes 10 and non-plated through holes 4 is also filled by the solder resist layer 15. The contact pads 7, contact areas 8 and solder balls 14 are not covered by the solder resist layer 15. The area between the active surface of the chip 2 and the upper surface of the redistribution board 3 is filled by underfill material 16.

The different paths by which moisture can exit the package to the environment are indicated by the arrows 17. Moisture exits the chip 2 and epoxy underfill 16 mainly downwards through the solder resist 15 located in the non-plated through holes 4 as well as through the plated via holes 10 and from the outer surfaces of the chip 2 and epoxy underfill 6 which are in contact with the environment.

Moisture contained within the core material 5 of the redistribution board 3 exits mainly through the side walls of the non-plated through holes 4 and the solder resist within them. For non-plated through holes 4 located under the semiconductor chip 2, the moisture exits mainly downwards. Moisture within the core material 5 also exits the redistribution board 3 from its outer surfaces.

FIG. 2 shows a cross-sectional view of an embodiment of the invention which includes a flip-chip semiconductor package 18 including a semiconductor chip 2 which is encapsulated by mold material 19. The redistribution board of the package 18 is essentially the same as that of package 1 shown in FIG. 1. Parts of the package which are similar have the same reference number and are not necessarily described again. The chip 2 and upper surface of the redistribution board 3 are covered by mold material 19. As indicated by the arrows 17, moisture exits the mold material 19 mainly through the solder resist within the via holes 10 and non-plated through holes 4 as well as through the outer surfaces of the mold material 19 which are in contact with the environment.

FIG. 3 shows a plan view of the upper surface of the redistribution board 3 of the semiconductor package 1, 18 of FIG. 1 or FIG. 2. Contact pads 7 are connected by conductive traces 6 to plated via holes 10. The redistribution board 3 also includes a plurality of non-plated through holes 4 which are laterally located in the redistribution board 3 between the conductive traces 6, contact pads 7 and plate via holes 10. Some of the non-plated through holes 4 are located towards the centre of the redistribution board 3 while others are located towards the outer edges of the redistribution board 3.

FIG. 4 shows a cross-sectional view of a flip-chip semiconductor package 20 including a semiconductor chip 2 according to a further embodiment of the invention. The redistribution board of the package 20 is similar to that of package 1 and 18 shown in FIGS. 1 and 2. Parts of the package which are similar have the same reference number and are not described again. In this embodiment of the invention, the redistribution board 21 includes non-plated through holes or vent holes 22 which are closed at the upper surface of the redistribution board 21 by a layer of solder resist 15. The vent holes 22 are not filled by solder resist.

The invention also relates to methods to assemble a substrate and a semiconductor package.

In the first step of the process, a redistribution board 3; 21 is provided. The redistribution board 3; 21 comprises a sheet of insulating core material 5 and a plurality of contact traces 6 and contact pads 7 on its upper surface, a second plurality of conducting traces 8 and external contact areas 9 on its bottom surface and conducting vias or plated via holes 10 connecting conducting traces 6 and lower conducting traces 8. A plurality of vent holes 4 are then drilled through the redistribution board 3, forming through-holes from the upper to the lower surface. The upper and lower surfaces of the redistribution board 3; 21 are then covered by a layer of solder resist 15 leaving the contact areas 6 and 8 free from solder resist 15.

In one embodiment of the invention the vent holes 4 are filled with solder resist 15. In an alternative embodiment, the vent holes 22 are closed at the upper surface of the redistribution board by solder resist 15.

The redistribution board 3; 21 assembled using one of the above method is then used assemble a semiconductor package 1; 18; 20. A semiconductor chip 2 comprising an active surface including a plurality of chip contact areas 13 is mounted on the upper surface of the redistribution board 3; 21 by microscopic solder balls 14 between the chip contacts 13 and upper contact pads 7.

The package 1 then undergoes a solder reflow heat treatment. The area between the chip 2 and the upper surface of the redistribution board 3; 21 is underfilled by epoxy resin or underfill material 16. Solder balls 12 are attached to the external contacts 9 of the redistribution board 3; 21. In an alternative embodiment of the method, after the semiconductor chip 2 is underfilled with underfill material 16, the upper surface of the chip 2 and redistribution board 3 are coated by mold material 19 to form an over-molded semiconductor package 18.

In an alternative method, the vent holes 4; 22 are drilled into the core material 5 of the redistribution board 3; 21 before the conductive traces 6 and 8, contact areas 7 and 9 and conducting vias 10 are deposited on the redistribution board 3; 21.

The semiconductor packages 1; 18; 20 are then tested, packaged and transported to the customer. The semiconductor packages are mounted to external substrates such as a printed circuit board.

### REFERENCE NUMBERS

1 semiconductor package
2 semiconductor chip
3 redistribution board
4 non-plated through hole
5 core material
6 upper conductive trace
7 upper contact pad
8 lower conductive trace
9 external contact area
10 plated via hole
11 metal coating
12 solder ball
13 chip contact area
14 microscopic solder ball
15 solder resist
16 underfill material
17 arrow
18 overmolded semiconductor package
19 mold material
20 semiconductor package
21 redistribution board
22 closed-end vent holes

What is claimed is:

1-16. (canceled)

17. A method to assemble a substrate for a semiconductor package comprising:
providing a substrate comprising a sheet of core material and a plurality of upper contact traces and upper contact pads on its upper surface, a second plurality of lower conducting traces and external contact areas on its bottom surface and conducting vias connecting the upper conducting traces and lower conducting traces;
forming a plurality of vent holes in the substrate; and
covering the upper and lower surfaces of the substrate by a layer of solder resist leaving the contact areas free from solder resist.

18. The method to assemble a substrate of claim 17, wherein the vent holes are closed at one end by a layer of solder resist on the upper surface of the substrate.

19. The method to assemble a substrate of claim 17, wherein the vent holes include solder resist.

20. The method to assemble a substrate of claim 17, wherein the vent holes are formed by drilling.

21. The method to assemble a substrate of claim 17, further comprising forming the vent holes in the core material before a plurality of upper contact traces and upper contact pads on its upper surface, a second plurality of lower conducting traces and external contact areas on its bottom surface and depositing conducting vias.

22. A method to assemble a semiconductor package comprising:
providing a substrate comprising a sheet of core material and a plurality of upper contact traces and upper contact pads on its upper surface, a second plurality of lower conducting traces and external contact areas on its bottom surface and conducting vias connecting the upper conducting traces and lower conducting traces;
forming a plurality of vent holes in the substrate;
covering the upper and lower surfaces of the substrate by a layer of solder resist leaving the contact areas free from solder resist;
providing a semiconductor chip comprising an active surface including a plurality of chip contact areas;
mounting the chip on the upper surface of the redistribution board by microscopic solder balls between the chip contacts and upper contact areas;
performing a solder reflow; and
underfilling the area between the chip and the upper surface of the redistribution board with epoxy resin.

23. A method to assemble a semiconductor package characterized in that the upper surface of the chip and substrate are covered with mold material.

24. A substrate for a semiconductor package comprising:
a sheet of core material;
a plurality of upper conducting traces and upper contact pads on an upper surface of the sheet, a second plurality of lower conductive traces and external contact areas on a bottom surface of the sheet and a plurality of conducting vias connecting the upper conducting traces and lower conducting traces;
a plurality of vent holes; and
a layer of solder resist covering the upper and lower surfaces of the substrate leaving the contact areas free from solder resist.

25. The substrate of claim 24, wherein the vent holes are include solder resist.

26. The substrate of claim 24, wherein the vent holes are closed at one end by a layer of solder resist on the upper surface of the substrate.

27. The substrate of claim 24, wherein the plurality of vent holes are laterally located towards the center of the substrate.

28. The substrate of claim 24, wherein the plurality of vent holes are laterally located towards the center and towards the outer edges of the substrate.

29. The substrate of claim 24, wherein the vent holes have a diameter of approximately 1 μm to approximately 5 mm or approximately 10 μm to approximately 0.5 mm or approximately 100 μm.

30. A semiconductor package comprising:
a sheet of core material;
a plurality of upper conducting traces and upper contact pads on an upper surface of the sheet, a second plurality of lower conductive traces and external contact areas on a bottom surface of the sheet and a plurality of conducting vias connecting the upper conducting traces and lower conducting traces;
a plurality of vent holes;
a layer of solder resist covering the upper and lower surfaces of the substrate leaving the contact areas free from solder resist;
a substrate; and
a semiconductor chip including an active surface with a plurality of chip contact areas, electrically connected to the substrate.

31. The semiconductor package of claim 30, wherein the chip is encapsulated by mold material.

32. The semiconductor package of claim 30, wherein the chip is mounted to the substrate by the flip-chip technique.

33. A substrate for a semiconductor package comprising:
a sheet of core material with an upper surface and a bottom surface each covered with a layer of solder resist;
a plurality of upper conducting traces and upper contact pads on the upper surface;
a plurality of bottom conductive traces and external contact areas on the bottom surface;
a plurality of conducting vias connecting the upper conducting traces and bottom conducting traces;
a plurality of vent holes; and
means for leaving the contact areas free from solder resist.

34. The substrate of claim 33, wherein the vent holes include solder resist.

35. The substrate of claim 33, wherein the vent holes are closed at one end by a layer of solder resist on the upper surface of the substrate.

36. The substrate of claim 33, wherein the plurality of vent holes are laterally located towards the center of the substrate.
